(19) United States
(12) Patent Application Publication
(10) Pub. No.: US 2013/0052756 A1
(43) Pub. Date: Feb. 28, 2013

(54) HEATING DEVICE AND SEMICONDUCTOR DEVICE MANUFACTURING METHOD

(71) Applicants: Shintaro Okujo, Oita (JP); Masato Fukumoto, Oita (JP)

(72) Inventors: Shintaro Okujo, Oita (JP); Masato Fukumoto, Oita (JP)

(73) Assignee: Kabushiki Kaisha Toshiba, Tokyo (JP)

(21) Appl. No.: 13/570,424

(22) Filed: Aug. 9, 2012

(30) Foreign Application Priority Data
Aug. 26, 2011 (JP) 2011-185332

(51) Int. Cl. H05B 1/02; H01L 21/66

(52) U.S. Cl. 438/7; 219/491; 257/E21.53

(57) ABSTRACT

A heating device is provided according to an embodiment. The heating device comprises a heater, a temperature detecting part, a wafer warpage detecting part and a controlling part. The heater heats a wafer. The temperature detecting part detects a temperature of the wafer. The wafer warpage detecting part detects warpage of the wafer. The controlling part controls the heater based on a detection result of the wafer warpage detecting part before controlling the heater based on a detection result of the temperature detecting part.

### CROSS-REFERENCE TO RELATED APPLICATIONS

This application is based upon and claims the benefit of priority from Japanese Patent Application No. 2011-185332, filed on Aug. 26, 2011; the entire contents of which are incorporated herein by reference.

### FIELD

Embodiments described herein relate generally to a heating device and a semiconductor device manufacturing method.

### BACKGROUND

A heating device is widely used in the steps of manufacturing a semiconductor device. For example, for the heating device, a heater such as a lamp heater heats a wafer thereby to perform thermal processing at a high temperature in a short time.

The heating device may cause warpage of the wafer when a temperature difference is present in the wafer plane.

### BRIEF DESCRIPTION OF THE DRAWINGS

FIGS. 1A to 1C are explanatory diagrams of thermal processing by a heating device according to an embodiment;

FIG. 2 is a diagram illustrating a structure of the heating device according to the embodiment;

FIGS. 3A to 3C and FIGS. 4A to 4C are diagrams illustrating relationships between warpage of a wafer and heating amount control of the wafer;

FIG. 5 is a diagram illustrating a positional relationship between a wafer and laser displacement meters;

FIGS. 6A, 6B, 7A and 7B are diagrams illustrating relationships between warpage of a wafer and an edge ring;

FIG. 8 is a diagram illustrating an exemplary relationship between a distance from a reference position to an outer periphery of the back surface of a wafer, and a time;

FIG. 9 is an explanatory diagram of a height for engaging a wafer at the edge ring; and

FIG. 10 is a flowchart illustrating control procedures performed by the heating device according to the embodiment.

### DETAILED DESCRIPTION

A heating device is provided according to an embodiment. The heating device comprises a heater, a temperature detecting part, a wafer warpage detecting part, and a controlling part. The heater heats a wafer. The temperature detecting part detects a temperature of the wafer. The wafer warpage detecting part detects warpage of the wafer. The controlling part controls the heater based on a detection result of the wafer warpage detecting part before controlling the heater based on a detection result of the temperature detecting part.

A heating device and a semiconductor device manufacturing method according to the embodiment of the present invention will be described below in detail with reference to the accompanying drawings. The present invention is not limited to the embodiment.

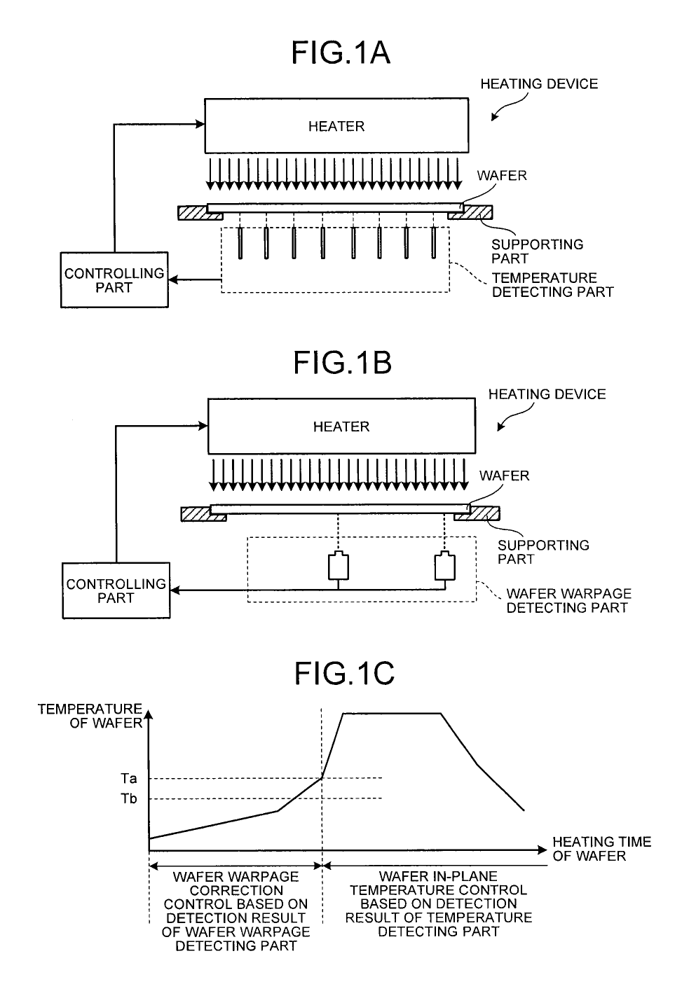

FIG. 1 is an explanatory diagram of thermal processing by the heating device according to the embodiment. The heating device according to the embodiment is used in the steps of manufacturing a semiconductor device, and is used in thermal processing of activating an impurity implanted into a wafer made of a semiconductor such as silicon.

As illustrated in FIG. 1A, the heating device according to the embodiment comprises the heater that heats a wafer supported by a supporting part. The heater includes a lamp heater comprising halogen lamps or xenon flash lamps, for example.

The heating device is provided with the temperature detecting part that detects a temperature of the wafer plane. The temperature detecting part includes radiation thermometers, for example, and detects a wafer in-plane temperature distribution. The controlling part in the heating device performs feedback control for the heater based on the wafer in-plane temperature distribution detected by the temperature detecting part such that a temperature in the wafer plane is uniform.

When a detectable temperature of the temperature detecting part is high, the wafer in-plane temperature can be measured until the detectable temperature of the temperature detecting part is reached after the heater starts heating the wafer.

However, if the feedback control for the heater is not performed before the detectable temperature of the temperature detecting part is reached, the wafer in-plane temperature is non-uniform and warpage can occur in the wafer. Additionally, when the wafer is heated while being rotated, if warpage of the wafer is larger, the wafer can drop off from the supporting part.

In the heating device according to the embodiment, at least until the detectable temperature of the temperature detecting part is reached, warpage of the wafer is detected by the wafer warpage detecting part and the feedback control for the heater is performed based on a detection result as illustrated in FIG. 1B. The wafer warpage detecting part includes laser displacement meters, for example, and detects displacements at a plurality of positions on the wafer by the laser displacement meters, thereby detecting warpage of the wafer.

FIG. 1C is an explanatory diagram of the feedback control based on a wafer warpage detection result. In FIG. 1C, the horizontal axis indicates a heating time of the heater for the wafer and the longitudinal axis indicates a temperature of the wafer.

As illustrated in FIG. 1C, the controlling part in the heating device first performs the feedback control for the heater for correcting warpage of the wafer based on the warpage of the wafer detected by the wafer warpage detecting part after the heater starts heating the wafer. Then, when the temperature of the wafer increases up to a state where the wafer in-plane temperature is measurable by the temperature detecting part, the controlling part in the heating device transits to the feedback control based on a detection result of the temperature detecting part.

In the example illustrated in FIG. 1C, the processing transits to the feedback control based on a detection result of the temperature detecting part under the condition that the wafer in-plane temperature increases up to a temperature Ta higher than a lower limit temperature Tb measurable by the temperature detecting part, but is not limited thereto. For example, the processing may transit to the feedback control based on a detection result of the temperature detecting part under the condition that the wafer in-plane temperature increases up to the lower limit temperature Tb measurable by the temperature detecting part.

The processing may transit to the feedback control based on a detection result of the temperature detecting part under the condition that a preset time elapses after the wafer starts being heated, not transiting to the feedback control based on a detection result of the temperature detecting part depending on the wafer in-plane temperature. In this case, a time when the wafer in-plane temperature accurately reaches the temperature Tb is previously set, for example.

In this way, the heating device according to the embodiment controls the heater based on a detection result of the wafer warpage detecting part before controlling the heater based on a detection result of the temperature detecting part. Thereby, the heater can be controlled to restrict warpage of the wafer even before the temperature detectable by the temperature detecting part is reached.

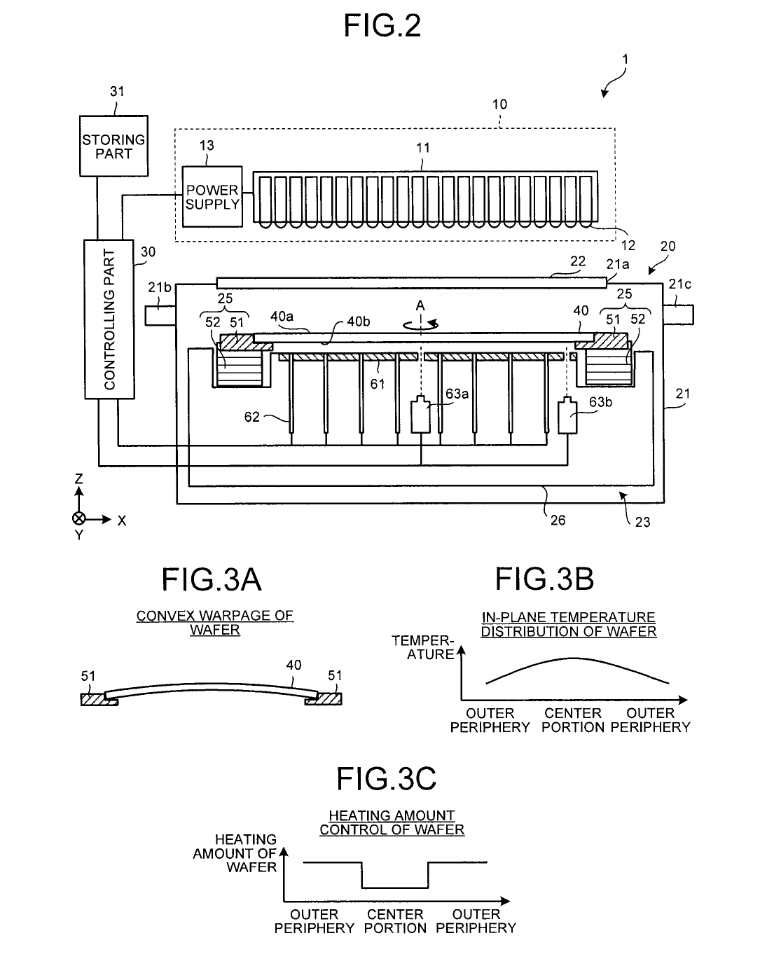

The heating device according to the embodiment will be described below more specifically. FIG. 2 is a diagram illustrating a structure of the heating device according to the embodiment.

As illustrated in FIG. 2, the heating device 1 comprises a heating part 10, a processing part 20, a controlling part 30 and a storing part 31. The heating device 1 is a thermal processing device which performs thermal processing of activating an impurity implanted into a wafer 40, for example, in the semiconductor device manufacturing steps. Herein, the heating device 1 includes a one-side heating and single-wafer RTA (Rapid Thermal Anneal) device by way of example, but is not limited thereto.

The temperature detecting part will be described herein by way of radiation thermometers, but the temperature detecting part is not limited thereto and any part capable of detecting an in-plane temperature distribution of the wafer 40 can be employed as the temperature detecting part. The wafer warpage detecting part will be described by way of laser displacement meters, but the wafer warpage detecting part is not limited thereto, and any part capable of detecting warpage of the wafer 40 can be employed as the wafer warpage detecting part.

The heating part 10 comprises a lamp heater 11 in which a plurality of lamps 12 are two-dimensionally arranged in the X direction and in the Y direction, and an illumination light is radiated from each lamp 12 to the wafer 40. The lamp 12 is a halogen lamp or xenon lamp, for example. The lamp 12 may include a lamp using noble gas, mercury or hydrogen, or a xenon arc discharge lamp.

The lamp heater 11 two-dimensionally arranges the lamps 12 therein as described above, and the amount of power to be supplied to each lamp 12 is changed depending on the position of the lamp 12 so that the amount of heating changes depending on the in-plane position of the wafer 40. The lamp heater 11 illustrated in FIG. 2 two-dimensionally arranges the lamps 12 therein, but may include a lamp heater in which bar-shaped lamps are arranged two-dimensionally, or a lamp heater in which circular lamps are arranged concentrically. The amount of heating can be changed depending on the in-plane position of the wafer 40 also with the structure.

A pulse light emission laser that emits various pulse lights may be used instead of the lamp heater 11. In this case, for example, a scanning part that scans a laser light emitted from the laser over the wafer 40 is provided to substantially emit the light over the entire wafer 40. Such a laser may be excimer laser, YAG laser, carbon monoxide gas laser or carbon dioxide gas laser, for example.

The heating part 10 is connected to a power supply 13 that supplies to each lamp 12 in the lamp heater 11. The power supply 13 may be included in the controlling part 30.

The processing part 20 comprises a processing chamber 21, a window 22 and a wafer supporting part 23. The processing chamber 21 can house the wafer 40 therein. The processing chamber 21 is formed with an opening 21a at a blocking portion between the internally-housed wafer 40 and the heating part 10. The opening 21a is blocked with the window 22 and the inside of the processing chamber 21 is made airtight. The processing chamber 21 is provided with a gas inlet port 21b and a gas outlet port 21c such that gas can be supplied inside as needed.

The window 22 is made of a translucent plate member. An illumination light emitted from the heating part 10 transmits through the window 22 so that the illumination light is radiated over the surface (the first surface) 40a of the wafer 40. The window 22 becomes higher in temperature due to the radiation of the illumination light, and thus the window 22 is made of a high heat-resistant material such as quartz.

The wafer supporting part 23 comprises a rotating part 25 and a base unit 26. The rotating part 25 comprises an edge ring 51 and a supporting part 52. The edge ring 51 is an annular member with a L-shaped cross section, and can hold the edge of the wafer 40 at its inner periphery. The edge ring 51 is supported at its lower part by the supporting part 52. The supporting part 52 is configured to be movable in an annular groove formed in the base unit 26 so that the rotating part 25 supporting the wafer 40 is rotatable about an axis A passing through the center of the wafer 40.

A reflecting plate 61 is arranged on the upper surface of the base unit 26, and the base unit 26 houses a plurality of radiation thermometer 62 and two laser displacement meters 63a, 63b.

The radiation thermometers 62 are arranged at different positions for detecting temperatures at different points on the back surface 40b (the second surface) of the wafer 40, and detect an in-plane temperature distribution of the wafer 40 based on input lights. The reflecting plate 61 is formed with an opening corresponding to the tip end of each radiation thermometer 62 such that a light is incident into each radiation thermometer 62.

The laser displacement meter 63a is arranged opposite to the center portion of the back surface 40b of the wafer 40 for detecting the position of the center portion of the wafer 40. The laser displacement meter 63b is arranged opposite to the outer periphery of the back surface 40b of the wafer 40 for detecting the position of the outer periphery of the wafer 40. The reflecting plate 61 is formed with openings corresponding to the laser displacement meters 63a and 63b that transmits a laser light.

The controlling part 30 controls the heating part 10 and the processing part 20. For example, the controlling part 30 controls the rotating part 25 to rotate the wafer 40 about the axis A.

The controlling part 30 controls the heating part 10 based on the in-plane temperature distribution of the wafer 40 detected by the radiation thermometers 62 during the feedback control by the radiation thermometers 62. Specifically, it controls the amount of supplied power to each lamp 12 in the lamp heater 11 based on the in-plane temperature distribution of the wafer 40. Thereby, an intensity of the light radiated from each lamp 12 (described as lamp power below) is adjusted so that the in-plane temperature of the wafer 40 uniformly increases.

The controlling part 30 controls the heating part 10 based on warpage of the wafer 40 detected by the laser displacement meters 63a and 63b during the feedback control by the laser displacement meters 63a and 63b.

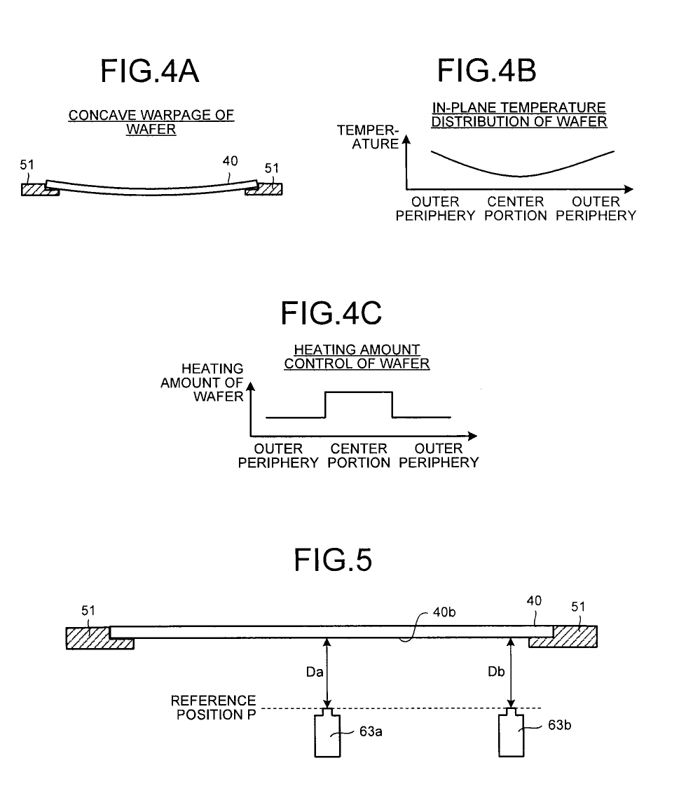

The feedback control by the laser displacement meters 63a and 63b will be specifically described below with reference to FIGS. 3A to 3C and FIGS. 4A to 4C. FIGS. 3A to 3C and FIGS. 4A to 4C are diagrams illustrating a relationship between warpage of the wafer 40 and heating amount control of the wafer 40.

At first, there will be described a case in which warpage of the wafer 40 is convex. Convex warpage is such that the center portion of the wafer 40 is closer to the lamp heater 11 than the outer periphery as illustrated in FIG. 3A.

When warpage of the wafer 40 is convex, the in-plane temperature distribution of the wafer 40 is as illustrated in FIG. 3B. That is, the temperature of the center portion is higher than the temperature of the outer periphery in the wafer 40.

Thus, when warpage of the wafer 40 is convex, the controlling part 30 further increases the amount of heating at the outer periphery of the wafer 40 than the amount of heating at the center portion of the wafer 40.

The amount of heating at the outer periphery of the wafer 40 changes depending on the amount of supplied power to the lamps 12 opposite to the outer periphery of the wafer 40. The amount of heating at the center portion of the wafer 40 changes depending on the amount of supplied power to the lamps 12 opposite to the center portion of the wafer 40.

When warpage of the wafer 40 is convex, the controlling part 30 further increases the amount of heating at the outer periphery of the wafer 40 than the amount of heating at the center portion of the wafer 40 as illustrated in FIG. 3C. In order to change the amount of heating of the wafer 40 to such a state, the controlling part 30 performs either processing of increasing the amount of supplied power to the lamps 12 opposite to the outer periphery of the wafer 40 by a predetermined amount or processing of decreasing the amount of supplied power to the lamps 12 opposite to the center portion of the wafer 40 by a predetermined amount, or performs both at the same time.

In this way, the amount of heating at the outer periphery of the wafer 40 is further increased than the amount of heating at the center portion of the wafer 40 so that a temperature increase rate at the outer periphery is higher than a temperature increase rate at the center portion in the wafer 40. Thus, the in-plane temperature distribution of the wafer 40 becomes more uniform.

Then, there will be described a case in which warpage of the wafer 40 is concave. Concave warpage is such that the outer periphery is closer to the lamp heater 11 than the center portion in the wafer 40 as illustrated in FIG. 4A.

When warpage of the wafer 40 is concave, the in-plane temperature distribution of the wafer 40 is as illustrated in FIG. 4B. That is, the temperature of the outer periphery is higher than the temperature of the center portion in the wafer 40.

Thus, when warpage of the wafer 40 is concave, the controlling part 30 further increases the amount of heating at the center portion of the wafer 40 than the amount of heating at the outer periphery of the wafer 40 as illustrated in FIG. 4C. In order to change the amount of heating of the wafer 40 to such a state, the controlling part 30 performs either processing of increasing the amount of supplied power to the lamps 12 opposite to the center portion of the wafer 40 by a predetermined amount or processing of decreasing the amount of supplied power to the lamps 12 opposite to the outer periphery of the wafer 40 by a predetermined amount, or performs both at the same time.

In this way, the amount of heating at the center portion of the wafer 40 is further increased than the amount of heating at the outer periphery of the wafer 40 so that a temperature increase rate at the center portion is higher than a temperature increase rate at the outer periphery in the wafer 40. Thus, the in-plane temperature distribution of the wafer 40 is more uniform.

Then, there will be described a case in which warpage of the wafer 40 is detected by the laser displacement meters 63a and 63b. FIG. 5 is a diagram illustrating a positional relationship between the back surface 40b of the wafer 40 and the laser displacement meters 63a, 63b.

As illustrated in FIG. 5, the laser displacement meter 63a measures a distance Da between a reference position P and the center portion of the back surface 40b of the wafer 40. The laser displacement meter 63b measures a distance Db between the reference position P and the outer periphery of the back surface 40b of the wafer 40.

When the wafer 40 is flat, the distance Da and the distance Db are the same. On the other hand, when convex warpage occurs in the wafer 40, the distance Da is longer than the distance Db, and when concave warpage occurs in the wafer 40, the distance Db is longer than the distance Da.

Thus, the controlling part 30 in the heating device 1 according to the present embodiment detects, based on the distance Da and the distance Db, that warpage occurs in the wafer 40 and whether the warpage is convex or concave.

The wafer 40 rotated by the rotating part 25 can drop off from the rotating part 25 due to its rotation force depending on a warpage state of the wafer 40. When the wafer 40 drops off from the rotating part 25, the wafer 40 jumps out due to a centrifugal force and can damage the inside of the processing chamber 21, the rotating part 25, the base unit 26 and the like.

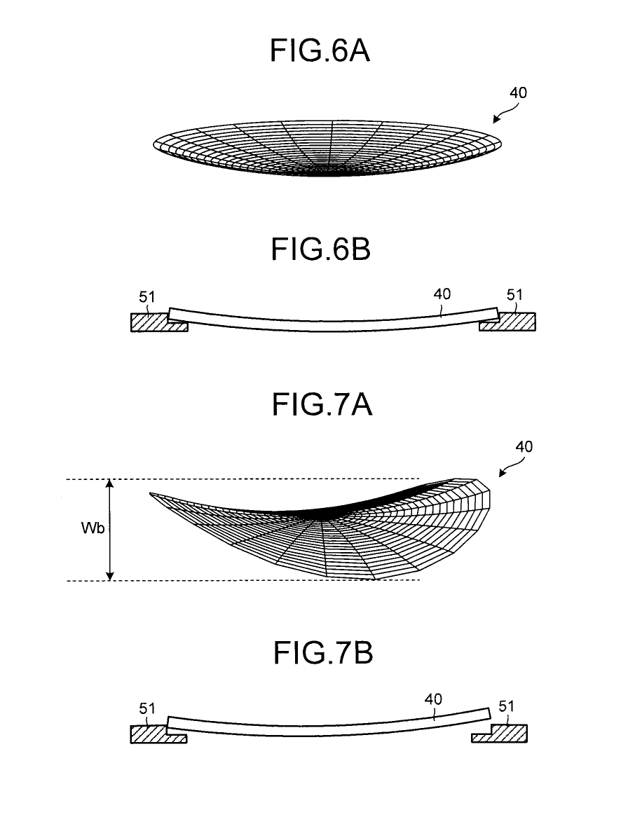

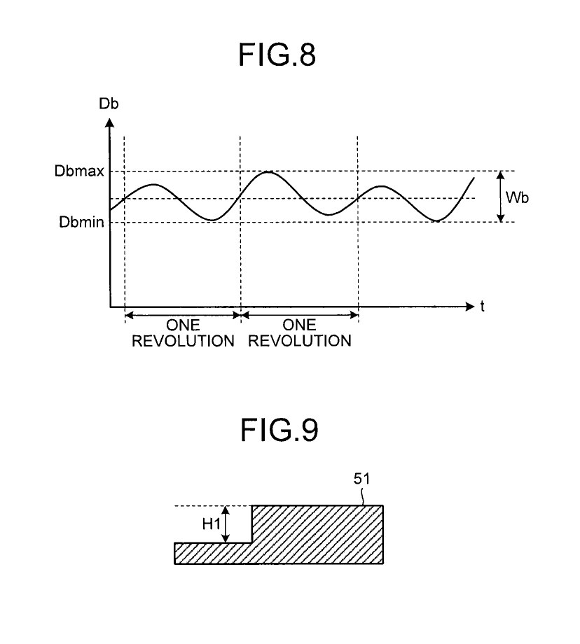

Thus, when concave warpage is present in the wafer 40, the controlling part 30 determines a likelihood of the dropping-off of the wafer 40 from the rotating part 25 based on an amplitude of the distance Db. FIGS. 6 and 7 are diagrams illustrating a relationship between warpage of the wafer 40 and the edge ring 51, FIG. 8 is a diagram illustrating an exemplary relationship between the distance Db and a time, and FIG. 9 is an explanatory diagram of a height for engaging the wafer 40 at the edge ring 51.

When warpage of the wafer 40 is concave and the warpage is uniform as illustrated in FIG. 6A, the outer periphery of the wafer 40 is engaged at the edge ring 51 as illustrated in FIG. 6B, for example. Thus, in such a case, the wafer 40 is less likely to drop off from the rotating part 25.

On the other hand, when warpage of the wafer 40 is concave and the warpage is non-uniform as illustrated in FIG. 7A, the wafer 40 can drop off from the rotating part 25. For example, as illustrated in FIG. 8, it is assumed that the distance Db varies between Dbmax and Dbmin until the wafer 40 rotates one revolution. In such a case, a difference Wb between Dbmax and Dbmin (described as outer periphery difference Wb below) may exceed a height H1 (refer to FIG. 9) of the edge ring 51.

When the outer periphery difference Wb (=Dbmax−Dbmin) exceeds the height H1 of the edge ring 51, the state as illustrated in FIG. 7B is reached, for example. Thus, part of the outer edge of the wafer 40 is not engaged at the edge ring 51 and the wafer 40 can drop off from the rotating part 25.

Thus, when the outer periphery difference Wb is equal to or more than a predetermined value, the controlling part 30 stops the rotation of the wafer 40 by the rotating part 25 and the processing of heating the wafer 40 by the heating part 10. Thereby, the fact prevents the wafer 40 from dropping off from the rotating part 25, and the inside of the processing chamber 21 and the like from being damaged. Even when warpage of the wafer 40 is concave and uniform and the outer periphery difference Wb is small as illustrated in FIG. 6A, when a difference between Da and Dbmax is equal to or more than a preset value, for example, the controlling part 30 can stop the rotation of the wafer 40 and the processing of heating the same.

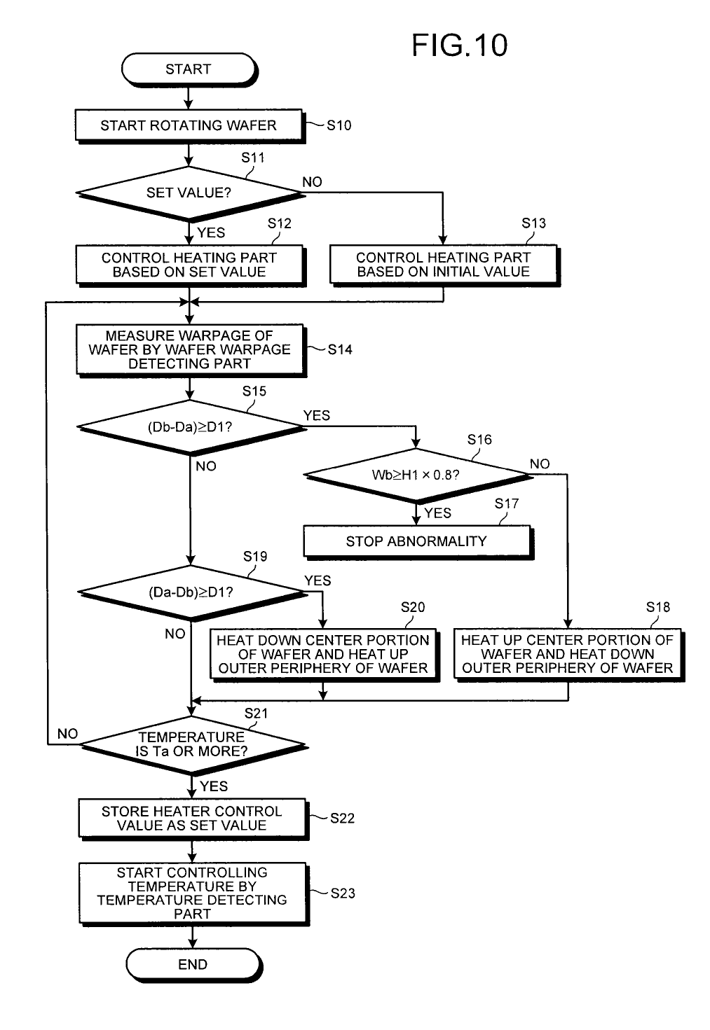

The processing procedures performed by the controlling part 30 in the heating device 1 according to the embodiment will be specifically described below with reference to FIG. 10. FIG. 10 is a flowchart illustrating the control procedures performed by the controlling part 30 in the heating device 1 according to the embodiment.

As illustrated in FIG. 10, the controlling part 30 first starts controlling the rotation of the rotating part 25, thereby to rotate the wafer 40 supported by the rotating part 25 about the axis A (step S10).

Then, the controlling part 30 determines whether an initial value is set in the storing part 31 (step S11). When determining that an initial value is set (step S11; Yes), the controlling part 30 reads the set value from the storing part 31 and controls the heating part 10 based on the set value (step S12). The set value is a past control value for the heating part 10, and thus can cause each lamp 12 to be operated by past-adjusted lamp power. The set value is stored in the storing part 31 in step S22 described later.

On the other hand, when determining that the set value is not set (step S11; No), the controlling part 30 reads the initial value from the storing part 31 and controls the heating part 10 based on the initial value (step S13). The initial value is a control value for supplying the same amount of power to each lamp 12, and thus can cause each lamp 12 to be operated at the same lamp power. The initial value is not limited to the control value, and may be to supply different power depending on the position of the lamp 12.

After the processing in step S12 or step S13 terminates, the controlling part 30 controls the laser displacement meters 63a and 63b as exemplary wafer warpage detecting part, and causes the laser displacement meters 63a and 63b to measure warpage of the wafer 40 (step S14). That is, the controlling part 30 causes the laser displacement meter 63a to detect the distance Da (refer to FIG. 5) between the reference position P and the center portion of the wafer 40 and causes the laser displacement meter 63b to detect the distance Db (refer to FIG. 5) between the reference position P and the outer periphery of the wafer 40.

Then, the controlling part 30 determines whether the following equation (1) is met (step S15). That is, the controlling part 30 determines whether concave warpage (refer to FIG. 4A) is present in the wafer 40 and whether the amount of concave warpage is equal to or more than D1.

(Db−Da)≧D1 (1)

When determining that the above equation (1) is met in step S15 (step S15; Yes), the controlling part 30 proceeds to step S16. On the other hand, when determining that the above equation (1) is not met (step S15; No), the controlling part 30 proceeds to step S19.

In step S16, the controlling part 30 detects the outer periphery difference Wb of the wafer 40 based on information on the distance Db output from the laser displacement meter 63b. The controlling part 30 determines whether the outer periphery difference Wb meets the following equation (2). That is, the controlling part 30 determines whether the outer periphery difference Wb is equal to or 0.8 times more than the height H1 of the edge ring 51.

Wb≧H1×0.8 (2)

When determining that the outer periphery difference Wb meets the above equation (2) (step S16; Yes), the controlling part 30 stops an abnormality (step S17). Specifically, the controlling part 30 stops the operations of the heating part 10 and the processing part 20. Thereby, the fact prevents the wafer 40 from dropping off from the rotating part 25, and the inside of the processing chamber 21 and the like from being damaged. The above equation (2) is exemplary. That is, the above equation (2) can be changed as needed as far as the wafer 40 does not drop.

On the other hand, when determining that the outer periphery difference Wb does not meet the above equation (2) (step S16; No), the controlling part 30 controls the heating part 10 to decrease the amount of heating at the outer periphery of the wafer 40 by a predetermined amount, and to increase the amount of heating at the center portion of the wafer 40 by a predetermined amount (step S18).

In step S19, the controlling part 30 determines whether the following equation (3) is met (step S19). That is, the controlling part 30 determines whether convex warpage (refer to FIG. 3A) is present in the wafer 40 and whether the amount of warpage is equal to or more than D1.

(Da−Db)≧D1 (3)

When determining that the above equation (3) is met (step S19; Yes), the controlling part 30 controls the heating part 10 to decrease the amount of heating at the center portion of the wafer 40 by a predetermined amount and to increase the amount of heating at the outer periphery of the wafer 40 by a predetermined amount (step S20).

When determining that the above equation (3) is not met in the processing in step S18, in the processing in step S20 and in step S19 (step S19; No), the controlling part 30 proceeds to step S21.

In step S21, the controlling part 30 determines whether the temperature of the wafer 40 is equal to or more than a predetermined temperature Ta. The predetermined temperature Ta is detectable by the radiation thermometers 62, and is 600° C., for example. The temperature of the wafer 40 is detectable by the radiation thermometers 62, but is not limited thereto and may be detected by other thermometer.

When determining that the temperature of the wafer 40 is not equal to or more than the predetermined temperature Ta (step S21; No), the controlling part 30 returns to step S14. On the other hand, when determining that the temperature of the wafer 40 is equal to or more than the predetermined temperature Ta (step S21; Yes), the controlling part 30 stores the current heater control value as the set value in the storing part 31 (step S22).

Herein, the heater control value is control information containing the amount of supplied power to the lamps 12 corresponding to the center portion of the wafer 40 (described as the center portion power amount below) and the amount of supplied power to the lamps 12 corresponding to the outer periphery of the wafer 40 (described as the outer periphery power amount below). A ratio between the center portion power amount and the outer periphery power amount may be stored as the heater control value in the storing part 31.

Thereafter, the controlling part 30 switches the feedback control for the heating part 10 based on the detection results of the laser displacement meters 63a and 63b to the feedback control for the heating part 10 based on the detection results of the radiation thermometers 62 as exemplary temperature detecting part (step S23). That is, the controlling part 30 calculates the amount of supplied power to each lamp 12 in the heating part 10 depending on the in-plane temperature distribution of the wafer 40 by the radiation thermometers 62 and supplies power to each lamp 12 in the heating part 10 based on the calculation result. Thereby, the lamp power of each lamp 12 depends on the in-plane temperature distribution of the wafer 40, and the wafer 40 is heated such that the in-plane temperature is uniform.

As described above, the heating device 1 according to the embodiment comprises the heating part 10 that heats the wafer 40, the radiation thermometers 62 that detects the temperature of the wafer 40, and the controlling part 30 that controls the heating part 10. Further, the heating device 1 comprises the laser displacement meters 63a and 63b that detects warpage of the wafer 40.

Then, the feedback control for the heating part 10 is performed based on the detection results of the laser displacement meters 63a and 63b before the feedback control for the heating part 10 is performed based on the detection results of the radiation thermometers 62.

Therefore, the feedback control for the heating part 10 can be performed even until the temperature of the wafer 40 can be measured by the radiation thermometers 62 after the heating part 10 starts heating the wafer 40. Thus, warpage of the wafer 40 can be restricted.

The controlling part 30 controls the heating part 10 such that a ratio between the amount of heating for the center portion of the wafer 40 and the amount of heating for the outer periphery (described as heating ratio below) is changed depending on a warpage direction of the wafer 40 detected by the laser displacement meters 63a and 63b. Thereby, the heating part 10 can be controlled such that a variation in the in-plane temperature of the wafer 40 can be restricted, thereby preventing warpage of the wafer 40.

The controlling part 30 can change the heating ratio depending on not only the warpage direction of the wafer 40 but also the warpage amount of the wafer 40. Thereby, warpage of the wafer 40 can be precisely controlled. For example, the controlling part 30 can adjust the heating ratio such that in the case of (Db−Da)>D1, as the value obtained by subtracting D1 from (Db−Da) is larger, the amount of heating for the center portion of the wafer 40 is larger than the amount of heating for the outer periphery. Further, for example, the controlling part 30 can adjust the heating ratio such that in the case of (Da−Db)>D1, as the value obtained by subtracting D1 from (Da−Db) is larger, the amount of heating for the outer periphery of the wafer 40 is larger than the amount of heating for the center portion.

The heating device 1 comprises the rotating part 25 that rotates the wafer 40. When warpage of the wafer 40 is in the predetermined state, the controlling part 30 stops controlling the rotating part 25, thereby to stop rotating the wafer 40. Thus, it is possible to prevent the wafer 40 from dropping off from the rotating part 25, and the inside of the processing chamber 21 and the like from being damaged. The “predetermined state” has been described in the above equation (2) by way of example, but the condition under which the control of the rotating part 25 is stopped is not limited thereto, and the control of the rotating part 25 can be stopped when the distance Db is equal to or more than the predetermined value, for example.

The heating device 1 comprises the storing part 31 that stores a control history for the heating part 10 performed by the controlling part 30. Then, the controlling part 30 can control the heating part 10 based on the control history stored in the storing part 31. With the same product and the same process, whether the wafer 40 is in the same rot or in a different rot, similar warpage occurs in the wafer 40 with the same heating processing. Thus, the control history for the past heating part 10 which has controlled the heating part 10 to restrict warpage of the wafer 40 to a certain amount or less is used thereby to properly control the heating part 10 for the wafer 40 with the same product and the same process. Thereby, the number of times of control for the heating part 10 by the controlling part 30 can be reduced, thereby rapidly performing the heating processing.

The control history is stored with the heater control value containing the center portion power amount and the outer periphery power amount as the set value in the storing part 31, but is not limited thereto. For example, the information based on the distance Da and the distance Db until the predetermined temperature Ta is reached after the heating part 10 starts heating the wafer 40 may be stored as the set value in the storing part 31. For example, an average value of the distance Da and an average value of the distance Db until the predetermined temperature Ta is reached after the wafer 40 starts being heated are calculated, and the average values are stored as the set values in the storing part 31. Even with this, for the wafer 40 with the same product and the same process, the heating part 10 can be properly controlled for the wafer 40 in the same rot or the wafer 40 in a different rot.

In the above example, the amounts of heating are controlled in the two regions of the center portion and the outer periphery of the wafer 40, respectively, but the amounts of heating can be controlled in three or more regions of the wafer 40.

In the above example, the control based on the detection results by the laser displacement meters 63a and 63b depending on the temperature of the wafer 40 is switched to the control based on the detection results by the radiation thermometers 62, but the control is not limited thereto. For example, the feedback control may be changed based on the heating time of the wafer 40 by the heating part 10. For example, the controlling part 30 previously sets information on a time ta in which the temperature of the wafer 40 is equal to or more than the predetermined temperature Ta in the storing part 31. Then, the controlling part 30 switches the feedback control when the time ta elapses after the heating part 10 starts heating the wafer 40.

In the above example, the amount of heating is adjusted by the heating part 10 when the difference between the distance Da and the distance Db is equal to or more than D1, but the adjustment is not limited thereto. For example, the controlling part 30 may detect a change rate per unit time of the difference between the distance Da and the distance Db and thereby may adjust the amount of heating by the heating part 10 such that the change rate is smaller. For example, the controlling part 30 increases the difference between the center portion power amount and the outer periphery power amount when the change rate is relatively large, and decreases the difference between the center portion power amount and the outer periphery power amount when the change rate is relatively small.

The heating device 1 which holds the outer edge of the wafer 40 by the edge ring 51 has been described in the above example, but is not limited thereto. For example, the heating device may be such that the back surface 40b of the wafer 40 is supported by a plurality of support pins and the support pins are rotated.

In the above example, warpage of the wafer 40 is detected by the two laser displacement meters 63a and 63b, but warpage of the wafer 40 may be detected by three or more laser displacement meters.

A changeable optical member may be provided between the center portion and outer periphery of the wafer 40, and the laser displacement meter 63a, thereby detecting the distance Da and the distance Db by the optical member in time division. In this way, the laser displacement meter 63a can detect the distance Da and the distance Db.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A heating device comprising:
a heater that heats a wafer;
a temperature detecting part that detects a temperature of the wafer;
a wafer warpage detecting part that detects warpage of the wafer; and
a controlling part that controls the heater,
wherein the controlling part controls the heater based on a detection result of the wafer warpage detecting part before controlling the heater based on a detection result of the temperature detecting part.

2. The heating device according to claim 1, wherein the controlling part controls the heater such that a ratio between the amount of heating for a center portion of the wafer and the amount of heating for an outer periphery of the wafer is changed depending on a warpage direction of the wafer and/or the warpage amount of the wafer detected by the wafer warpage detecting part.

3. The heating device according to claim 2, wherein when the wafer is convex such that the center portion is closer to the heater than the outer periphery, the controlling part further increases the amount of heating for the outer periphery of the wafer than the amount of heating for the center portion of the wafer.

4. The heating device according to claim 2, wherein when the wafer is concave such that the outer periphery is closer to the heater than the center portion, the controlling part further increases the amount of heating for the center portion of the wafer than the amount of heating for the outer periphery of the wafer.

5. The heating device according to claim 2, wherein when the warpage amount of the wafer detected by the wafer warpage detecting part is equal to or more than a predetermined amount or when a change rate of the warpage amount of the wafer detected by the wafer warpage detecting part is equal to or more than a predetermined rate, the controlling part changes the ratio between the amount of heating for a center portion of the wafer and the amount of heating for an outer periphery of the wafer.

6. The heating device according to claim 1, wherein the temperature detecting part includes a radiation thermometer, and
the controlling part controls the heater based on a detection result of the wafer warpage detecting part at least until a temperature of the wafer reaches a detectable temperature by the radiation thermometer.

7. The heating device according to claim 1, wherein the wafer warpage detecting part includes a first laser displacement meter that measures a distance between a reference position and the center portion of the wafer and a second laser displacement meter that measures a distance between a reference position and the outer periphery of the wafer, and detects warpage of the wafer based on a measurement result by the first laser displacement meter and a measurement result by the second laser displacement meter.

8. The heating device according to claim 7, comprising a rotating part that rotates the wafer,
wherein when a variation in the measurement result by the second laser displacement meter is equal to or beyond a predetermined range, the controlling part stops controlling the rotating part thereby to stop rotating the wafer.

9. The heating device according to claim 1, comprising a rotating part that rotates the wafer,
wherein when warpage of the wafer detected by the wafer warpage detecting part enters a predetermined state, the controlling part stops controlling the rotating part thereby to stop rotating the wafer.

10. The heating device according to claim 1, comprising a storing part that stores a control history for the heater performed by the controlling part,
wherein the controlling part controls the heater based on the control history stored in the storing part.

11. A semiconductor device manufacturing method, comprising:
(A) detecting warpage of a wafer until a predetermined condition is met;
(B) heating the wafer depending on warpage of the wafer;
(C) detecting a temperature of the wafer after the predetermined condition is met; and
(D) heating the wafer depending on a temperature of the wafer.

12. The semiconductor device manufacturing method according to claim 11, wherein the (B) heating includes changing a ratio between the amount of heating for a center portion of the wafer and the amount of heating for an outer periphery of the wafer depending on a warpage direction of the wafer and/or the warpage amount of the wafer until the predetermined condition is met.

13. The semiconductor device manufacturing method according to claim 12, wherein the changing includes increasing the amount of heating for the outer periphery of the wafer than the amount of heating for the center portion of the wafer when the wafer is convex such that the center portion is closer to a heater that heats the wafer than the outer periphery.

14. The semiconductor device manufacturing method according to claim 12, wherein the changing includes increasing the amount of heating for the center portion of the wafer than the amount of heating for the outer periphery of the wafer when the wafer is concave such that the outer periphery is closer to a heater that heats the wafer than the center portion.

15. The semiconductor device manufacturing method according to claim 12, wherein the changing is performed when the warpage amount of the wafer is equal to or more than a predetermined amount or when the change rate of the warpage amount of the wafer is equal to or more than a predetermined rate.

16. The semiconductor device manufacturing method according to claim 11, wherein the (B) heating is performed until the temperature of the wafer reaches a detectable temperature by a radiation thermometer.

17. The semiconductor device manufacturing method according to claim 11, comprising:
measuring a distance between a reference position and the center portion of the wafer by a first laser displacement meter;
measuring a distance between a reference position and the outer periphery of the wafer by a second laser displacement meter; and
wherein the detecting is performed based on a measurement result by the first laser displacement meter and a measurement result by the second laser displacement meter.

18. The semiconductor device manufacturing method according to claim 17, comprising:
stopping controlling a rotating part that rotates the wafer thereby to stop rotating the wafer when a measurement result by the second laser displacement meter is equal to or beyond a predetermined range.

19. The semiconductor device manufacturing method according to claim 11, comprising:
stopping controlling a rotating part that rotates the wafer thereby to stop rotating the wafer when warpage of the wafer enters a predetermined state.

20. The semiconductor device manufacturing method according to claim 11, comprising:
controlling the heater based on a control history for a heater that heats the wafer.
